(19) United States
(12) Patent Application Publication
(10) Pub. No.: US 2025/0059401 A1
(43) Pub. Date: Feb. 20, 2025

(54) CHEMICAL MECHANICAL POLISHING SOLUTION AND USAGE METHOD THEREOF

(71) Applicant: ANJI MICROELECTRONICS (SHANGHAI) CO., LTD, Shanghai (CN)

(72) Inventors: Pengyu Xu, Shanghai (CN); Xingping Wang, Shanghai (CN); Shoutian Li, Shanghai (CN)

(21) Appl. No.: 18/722,496

(22) PCT Filed: Dec. 23, 2022
(86) PCT No.: PCT/CN2022/141289

§ 371 Date: Jun. 20, 2024

(30) Foreign Application Priority Data
Dec. 23, 2021 (CN) 202111592296.7

(51) Int. Cl. C09G 1/02; H01L 21/3105

(52) U.S. Cl. CPC C09G 1/02; H01L 21/31053

(57) ABSTRACT

The present disclosure provides a chemical mechanical polishing solution comprising cerium oxide particles, an anionic compound, a cationic compound, an inhibitor, and a pH regulator, wherein the inhibitor is a non-ionic polymeric compound; The polishing selectivity ratio of the chemical mechanical polishing solution for the insulation film/polycrystalline silicon is greater than 100. The chemical mechanical polishing solution of the present invention can effectively maintain a high polishing selectivity ratio of the insulation layer to the stop layer, where the stop layer is a polycrystalline silicon stop layer.

### CROSS-REFERENCE TO RELATED APPLICATIONS

This application is a National Stage of PCT/CN2022/141289, filed Dec. 23, 2022, published on Jun. 29, 2023, as WO 2023/116867 A1, which claims priority to Chinese Patent Application No. 202111592296.7, filed Dec. 23, 2021, each hereby expressly incorporated by reference in its entirety.

### TECHNICAL FIELD

This present disclosure relates to the field of chemical mechanical polishing, particularly to a chemical mechanical polishing solution and usage method thereof.

### BACKGROUND

In recent years, the high-density and miniaturization technologies in semiconductor material fabrication have been deepening, becoming increasingly important. As a part of the flattening process, CMP technology has also been receiving more attention.

In current technology, chemical mechanical polishing has become an essential technique for forming shallow trench isolation and for planarizing metal pre-insulating materials or interlayer insulating materials. In STI formulations, in addition to containing abrasive particles, they typically also include various additives, inhibitors, and pH regulators.

The most widely used CMP polishing solution is silicon dioxide-based, but cerium oxide polishing solution is also growing in popularity. Cerium oxide polishing solution has its characteristics, for example, compared to silicon dioxide-based CMP, cerium oxide particles can still provide a high polishing rate at lower concentrations.

At the same time, cerium oxide polishing solution can achieve a higher selectivity ratio, which is of great practical value in STI structure polishing. For different stop layers, such as silicon nitride or polycrystalline silicon, high selectivity is required, and there is an urgent need for a CMP polishing solution with high polishing selectivity for silicon dioxide/polycrystalline silicon stop layers.

### SUMMARY

In view of the above technical problems, this invention proposes a chemical mechanical polishing (CMP) solution, including: cerium oxide particles, an anionic compound, a cationic compound, an inhibitor, and a pH regulator; wherein the inhibitor is a nonionic polymer compound; and the CMP solution has a selectivity ratio of more than 100 for polishing the insulating film phase/polycrystalline silicon.

Preferably, the cerium oxide particles are sol-gel type cerium oxide particles.

Preferably, the anionic compound is selected from phosphate compounds or anionic polymers.

Preferably, the phosphate compound is selected from phosphoric acid, potassium phosphate, or dipotassium hydrogenphosphate; and the anionic polymer is selected from ammonium polyacrylate or polyaspartic acid.

Preferably, a mass percentage ratio of the anionic compound to ceria oxide particles is 0.01-2.

Preferably, the cationic compound is a polyquaternium.

Preferably, the polyquaternium is selected from polyquaternium-2, polyquaternium-6, polyquaternium-7, polyquaternium-28, polyquaternium-37.

Preferably, the cationic compound is selected from aluminum nitrate or arginine.

Preferably, a mass percentage ratio of the cationic compound to ceria oxide particles is 0.01 to 0.5.

Preferably, a mass percentage ratio of the cationic compound to ceria oxide particles is 0.05 to 0.3.

Preferably, the inhibitor is selected from polyethylene glycol and its derivatives, polyoxyethylene and its derivatives.

Preferably, a molecular weight of the inhibitor is 1000-100,000.

Preferably, a mass percentage ratio of the inhibitor to the ceria oxide particles is 0.1-2.

Another aspect of the invention provides an application method for using any of the above-mentioned ceria oxide in polishing silicon oxide.

Compared to the existing technologies, the specified anionic compounds, cationic compounds, and inhibitors in this application can effectively control the selectivity ratio of the insulation film to the polycrystalline silicon stop layer, thereby improving the planarization efficiency and protecting the polycrystalline silicon stop layer, ensuring the smooth implementation of the STI process.

### DETAILED DESCRIPTION

The following specific embodiments are further elucidated to illustrate the advantages of the present invention.

According to the proportions of the components in Table 1, dissolve each component in deionized water and add deionized water until the total is 100%. The percentages in Table 1 are all mass percentages. Mix and ultrasonically stir for 30 minutes to disperse the mixture. Then, dilute with deionized water until the cerium oxide content is 0.2 wt %, and use nitric acid as the pH regulator to adjust the polishing solution pH to 4.8.

| | | Anionic compounds | | Cationic compounds | | Inhibitor | |
|---|---|---|---|---|---|---|---|
| polishing | Cerium | Specific | Concen- | Specific | Concen- | Specific | Concen- |
| solution | oxide | compounds | tration | compounds | tration | compounds | tration |
| Embodiment 1 | 10% | Ammonium | 4.5% | polyquaternium-7 | 2.5% | Polyethylene | 5% |
| | | Polyacrylate + | | | | glycol (PEG) | |
| | | Polyaspartic acid | | | | | |
| Embodiment 2 | 10% | Ammonium | 10.4% | polyquaternium-7 | 2.5% | Polyoxyethylene | 3% |
| | | Polyacrylate | | | | stearate | |
| Embodiment 3 | 10% | Ammonium | 1.9% | polyquaternium-7 | 2.5% | Polyethylene | 5% |
| | | Polyacrylate | | | | glycol (PEG) | |
| Embodiment 4 | 10% | Dipotassium | 7.5% | polyquaternium-37 | 2.5% | Polyethylene | 5% |
| | | hydrogenphosphate | | | | glycol (PEG) | |
| Comparative | 10% | Polyaspartic acid | 10.7% | polyquaternium-7 | 2.5% | Polyethylene | 5% |
| Embodiment 1 | | | | | | glycol (PEG) | |
| Comparative | 10% | Ammonium | 0.4% | polyquaternium-7 | 7.5% | Polyethylene | 5% |
| Embodiment 2 | | Polyacrylate | | | | glycol (PEG) | |
| Comparative | 10% | Ammonium | 0.4% | polyquaternium-7 | 12.5% | — | — |
| Embodiment 3 | | Polyacrylate | | | | | |

In order to further measure the polishing performance of the polishing solutions in each Embodiment and the Comparative Embodiment, the polishing rates of the polishing solutions on TEOS insulating wafer and polysilicon wafer were measured separately. The specific polishing conditions were as follows:

Polishing Equipment: Mirra polishing machine; IC1010 polishing pads; NanoSpec film thickness measurement system (NanoSpec 6100-300, Shanghai Nanospec Technology Corporation).

Polishing conditions: The platen and carrier speeds are set at 93 rpm and 87 rpm, respectively. The polishing pressure is 2.0 psi, and the polishing liquid flow rate is 150 mL/min.

Polishing steps: Use the polishing solutions obtained above to polish the TEOS and polycrystalline silicon blank wafers using the above polishing instruments and conditions, and perform polishing treatment. Start from the edge of the wafer 3 mm in diameter, measure 49 points equally spaced on the diameter line, and test the polishing rate of each point separately. Therefore, the polishing rate of each polishing solution is the average of the polishing rates of the 49 points.

The polishing rates as measured are shown in Table 2.

Table 2 shows the polishing rates for Embodiments 1-4 compared to Comparative Embodiment 1-3

| | 200 mm CMP | | Selection |
|---|---|---|---|
| | | Polycrystalline | ratio (TEOS/ |
| polishing | TEOS | silicon | Polycrystalline |
| solution | RR(Å/min) | RR(Å/min) | silicon) |
| Embodiment 1 | 2057 | 2 | 1029 |
| Embodiment 2 | 1820 | 7 | 260 |
| Embodiment 3 | 3478 | 1 | 3478 |
| Embodiment 4 | 3096 | 5 | 619 |
| Comparative | 2105 | 408 | 5 |
| Embodiment 1 | | | |
| Comparative | 2093 | 150 | 14 |
| Embodiment 2 | | | |
| Comparative | 115 | 1000 | 0.1 |
| Embodiment 3 | | | |

According to the test results of Embodiments 1-4 in Table 2, when three additives are added simultaneously, the polishing selectivity of the insulating film phase/polycrystalline silicon can reach over 100, and the removal rate of the insulating film is also maintained at a high level.

Furthermore, comparing the polishing rates of Embodiment 1 and Embodiment 2 with Comparative Embodiment 1, it can be seen that the use of only one anionic compound, polyaspartic acid, in Comparative Embodiment 1 maintains a relatively high level of polishing rate for the insulating layer. However, it does not provide sufficient protection for polycrystalline silicon, resulting in a polishing selectivity of only 5. When only using one type of polyamino acid, it cannot provide adequate protection for the polycrystalline silicon stop layer. Moreover, when using both ammonium polyacrylate and polyaspartic acid together, the insulation film polishing rate of the polishing solution is higher, and the polishing selectivity of the polishing solution is even more excellent.

Based on the polishing rate data of Comparative Embodiment 2, it can be seen that the excessive addition of cationic substances will have an adverse effect on the protection of the polycrystalline silicon stop layer. By using the cationic amount disclosed in this application, the polishing solution can have excellent protective effects on the polycrystalline silicon stop layer while maintaining a relatively high insulation film polishing rate.

Comparative Embodiment 3 demonstrates that without the addition of inhibitors and excessive cationic substances, the polycrystalline silicon stop layer cannot be protected.

In summary, the use of the anionic compounds, cationic compounds, and inhibitors specified in this application effectively controls the selectivity of the insulation film relative to the polycrystalline silicon stop layer, thereby significantly improving planarization efficiency and protecting the polycrystalline silicon stop layer. This ensures the smooth implementation of the STI process.

It should be noted that the embodiments of the present invention are exemplary and not intended to limit the scope of the invention in any form. Those skilled in the art may make changes or modifications to the disclosed technical content to create equivalent and effective embodiments. Any modifications or equivalent changes and modifications made to the above embodiments based on the technical essence of the present invention are still within the scope of the technical solution of the present invention.

1. A chemical mechanical polishing (CMP) solution, comprising cerium oxide particles, an anionic compound, a cationic compound, an inhibitor, and a pH regulator; wherein the inhibitor is a nonionic polymer compound; and the CMP solution has a selectivity ratio for polishing insulating film/polycrystalline silicon higher than 100.

2. The chemical mechanical polishing solution according to claim 1, characterized in that the cerium oxide particles are in sol-gel form.

3. The chemical mechanical polishing solution according to claim 1, characterized in that the anionic compounds are selected from phosphate compounds or anionic polymers.

4. The chemical mechanical polishing solution according to claim 3, characterized in that, the phosphate compounds are selected from phosphoric acid, potassium phosphate, or dipotassium hydrogenphosphate; the anionic polymers are selected from ammonium polyacrylate, a mixture of ammonium polyacrylate and polyaspartic acid.

5. The chemical mechanical polishing solution according to claim 1, characterized in that, a mass percentage ratio of the anionic compound to ceria oxide particles is 0.01-2.

6. The chemical mechanical polishing solution according to claim 1, characterized in that, the cationic compound is a polyquaternium.

7. The chemical mechanical polishing solution according to claim 6, characterized in that, the polyquaternium is selected from polyquaternium-2, polyquaternium-6, polyquaternium-7, polyquaternium-28, polyquaternium-37.

8. The chemical mechanical polishing solution according to claim 1, characterized in that, the cationic compounds are selected from aluminum nitrate or arginine.

9. The chemical mechanical polishing solution according to claim 1, characterized in that, a mass percentage ratio of the cationic compound to ceria oxide particles is 0.01 to 0.5.

10. The chemical mechanical polishing solution according to claim 9, characterized in that, a mass percentage ratio of the cationic compound to ceria oxide particles is 0.05 to 0.3.

11. The chemical mechanical polishing solution according to claim 1, characterized in that, the inhibitor is selected from polyethylene glycol and its derivatives, polyethylene oxide and its derivatives.

12. The chemical mechanical polishing solution according to claim 1, characterized in that, a molecular weight of the inhibitor is 1000-100,000.

13. The chemical mechanical polishing solution according to claim 1, characterized in that, a mass percentage ratio of the inhibitor to the ceria oxide particles is 0.1-2.

14. A method of polishing insulating films using any one of the chemical mechanical polishing solution as claimed in claim 1.
